(19) United States
(12) Patent Application Publication
(10) Pub. No.: US 2024/0404904 A1
(43) Pub. Date: Dec. 5, 2024

(54) ELECTRONIC DEVICE AND METHOD OF MANUFACTURING THE SAME

(71) Applicant: InnoLux Corporation, Miao-Li County (TW)

(72) Inventors: Ker-Yih KAO, Miao-Li County (TW); Wei-Yuan CHENG, Miao-Li County (TW); Ju-Li WANG, Miao-Li County (TW)

(21) Appl. No.: 18/655,448

(22) Filed: May 6, 2024

Related U.S. Application Data
(60) Provisional application No. 63/505,457, filed on Jun. 1, 2023.

(30) Foreign Application Priority Data
Mar. 4, 2024 (CN) 202410241497.X

(51) Int. Cl. H01L 23/31; H01L 23/00

(52) U.S. Cl. CPC H01L 23/3135; H01L 24/19; H01L 24/20; H01L 24/24; H01L 24/82; H01L 2224/19; H01L 2224/2105; H01L 2224/211; H01L 2224/214; H01L 2224/215; H01L 2224/24137; H01L 2224/82005; H01L 2924/01022; H01L 2924/01024; H01L 2924/01028; H01L 2924/01029; H01L 2924/01042; H01L 2924/01047; H01L 2924/01073; H01L 2924/01074; H01L 2924/01078; H01L 2924/01079

(57) ABSTRACT

An electronic device includes an electronic component including a chip and a protective layer disposed on the active surface of the chip; an encapsulation layer surrounding the electronic component; and a circuit structure contacting the first surface of the encapsulation layer and electrically connecting the electronic component. The protective layer has a second surface away from the active surface, and a first step difference between the first surface and the second surface is between 1 and 10 μm.

### CROSS REFERENCE TO RELATED APPLICATIONS

This application claims the benefit of China Patent Application No. 202410241497.X, filed on Mar. 4, 2024, and provisional Application No. 63/505,457, filed Jun. 1, 2023, the entirety of which is incorporated by reference herein.

### BACKGROUND OF THE INVENTION

### Field of the Invention

The present disclosure relates to an electronic device and a method of manufacturing the same, and in particular it relates to an electronic device comprising a circuit structure and a method of manufacturing the same.

### Description of the Related Art

An electronic device includes an electronic component and a circuit structure. The circuit structure includes a conductive layer and an insulating layer. During the process of manufacturing the electronic device, the circuit structure may become cracked, damaged or delaminated due to the difference in thermal expansion coefficient between the conductive layer and the insulating layer, thereby reducing the reliability of the electronic device.

### BRIEF SUMMARY OF THE INVENTION

An embodiment of the present disclosure provides an electronic device. The electronic device includes an electronic component, an encapsulation layer, and a circuit structure. The electronic component includes a chip and a protective layer disposed on the active surface of the chip. The encapsulation layer surrounds the electronic component. The circuit structure is in contact with the first surface of the encapsulation layer and electrically connects the electronic component. The protective layer has a second surface away from the active surface, and a first step difference between the first surface and the second surface is between 1 and 10 μm.

An embodiment of the present disclosure provides a method of manufacturing an electronic device. The method includes providing an encapsulation layer surrounding an electronic component; providing a first conductive layer and a first conductive component on the electronic component and the encapsulation layer; performing a first surface treatment process on the first conductive component; providing a first insulating layer on the first conductive component subjected to the first surface treatment process; performing a flattening process; and performing a second surface treatment process. The electronic component includes a chip and a protective layer covering an active surface of the chip. The protective layer has a second surface. The encapsulation layer has a first surface. The second surface and the first surface are separated by a first step difference. The first step difference is between 1 and 10 μm.

An embodiment of the present disclosure provides a method of manufacturing an electronic device. The method includes providing an encapsulation layer surrounding at least two electronic components; providing a first conductive layer and a first conductive component on one of the electronic components and the encapsulation layer; performing a first surface treatment process on the first conductive component; providing a first insulating layer on the first conductive layer, the first conductive component, and the other electronic component; forming a third opening through the encapsulation layer between the at least two electronic components; forming a second conductive layer and a second conductive component on the other electronic component and in the third opening to electrically connect the at least two electronic components; providing a second insulating layer on the second conductive layer and the second conductive component; performing a flattening process; and performing a second surface treatment process. The electronic component includes a chip and a protective layer covering the active surface of the chip. The protective layer has a second surface. The encapsulation layer has a first surface. The second surface and the first surface are separated by a first step difference. The first step difference is between 1 and 10 μm.

### BRIEF DESCRIPTION OF THE DRAWINGS

The present disclosure can be more fully understood by reading the subsequent detailed description and examples with references made to the accompanying drawings, wherein:

FIG. 1A is a schematic cross-sectional view of an electronic device according to an embodiment of the present disclosure;

FIG. 1B is an enlarged schematic view of a region A of FIG. 1A;

FIG. 1C is an enlarged schematic view of a region B of FIG. 1B;

FIG. 2 is a flowchart of a method of manufacturing an electronic device according to an embodiment of the present disclosure;

FIGS. 3A to 3F are schematic cross-sectional views of semi-finished products of an electronic device at various stages of a method of manufacturing an electronic device according to an embodiment of the present disclosure;

FIGS. 4A to 4D are schematic cross-sectional views of semi-finished products of an electronic device at various stages of a method of manufacturing an electronic device according to another embodiment of the present disclosure;

FIG. 5 is a flowchart of a method of manufacturing an electronic device according to an embodiment of the present disclosure;

FIGS. 6A to 6C are schematic cross-sectional views of semi-finished products of an electronic device at various stages of a method of manufacturing an electronic device according to another embodiment of the present disclosure;

FIG. 6D is an enlarged schematic view of a region E of FIG. 6C;

FIG. 7 is a flowchart of a method of manufacturing an electronic device according to an embodiment of the present disclosure; and

FIGS. 8A to 8F are schematic cross-sectional views of semi-finished products of an electronic device at various stages of a method of manufacturing an electronic device according to another embodiment of the present disclosure.

### DETAILED DESCRIPTION OF THE INVENTION

The following description is made for the purpose of illustrating the general principles of the disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

The directional terms mentioned in the disclosure, such as “up”, “down”, “front”, “back”, “left”, “right” only refer to the directions of the accompanying drawings. Therefore, the directional terms used herein are illustrative and not intended to limit the disclosure. It should be understood that if a device in an accompanying drawing is turned so that it is upside down, components recited on the “bottom” side will become the components on the “top” side. In the accompanying drawings, the drawings illustrate general features of the methods, structures and/or materials used in specific embodiments. However, these accompanying drawings should not be construed as defining or limiting the scope or property of what is covered by these embodiments. For example, relative sizes, thicknesses and positions of the various layers, regions and/or structures may be reduced or enlarged for clarity.

In the present disclosure, descriptions of a structure (or layer, component or substrate) being on/above another structure (or layer, component or substrate) may mean that the two structures are adjacent and directly connected, or that the two structures are adjacent and indirectly connected. Indirect connection means that there is at least one intermediate structure (or intermediate layer, intermediate component, intermediate substrate, intermediate spacer) between two structures. A lower surface of the structure is adjacent to or directly connected to an upper surface of the intermediate structure, and an upper surface of the other structure is adjacent to or directly connected to a lower surface of the intermediate structure. The intermediate structure may be a single-layer or multi-layer physical structure or a non-physical structure without limitation. In the disclosure, when a structure is disposed “on” another structure, it may mean that the structure is “directly” on the other structure, or that the structure is “indirectly” on the other structure, i.e. there is at least one structure is between the structure and the other structure.

The present disclosure may be understood by referring to the following detailed description and combined with the accompanying drawings. It should be noted that in order to make it easy for readers to understand and for the simplicity of the drawings, many of the drawings in the present disclosure only depict a portion of an electronic device, and certain components in the drawings are not drawn to actual scale. In addition, the number and size of components in the drawings are only for illustration and are not intended to limit the scope of the present disclosure.

Throughout the disclosure and the appended claims, some terms are used to refer to specific components. Those skilled in the art will understand that electronic device manufacturers may refer to the same component by different names. The disclosure is not intended to differentiate between components that have the same function but have different names.

In some embodiments of the present disclosure, unless otherwise defined, terms related to joining and connecting, such as “connection”, “interconnection”, etc., may mean that two structures are in direct contact, or may also mean that the two structures are not in direct contact (indirect contact) and other structures are between the two structures. The terms related to joining and connecting may also include the situation where both structures are movable or both structures are fixed. In addition, the term “electrical connection” includes a transfer of energy between two structures by direct or indirect electrical connection, or a transfer of energy between two separate structures by mutual induction.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. The term “a-b” refers to a range that includes all values greater than or equal to a, less than or equal to b, and all values between a and b.

Ordinal numbers used in the specification and claims, such as “first”, “second”, etc., are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second component in the claim.

It should be understood that according to the embodiments of the present disclosure, the depth, thickness, width or height of each element, or the space of the components or the distance between them may be measured using an optical microscope (OM), a scanning electron microscope (SEM), a film thickness profile measuring gauge (α-step), an elliptical thickness gauge, or other suitable measurement methods. According to some embodiments, a scanning electron microscope may be used to obtain a cross-sectional structural image including the components to be measured, and to measure the depth, thickness, width or height of each component, or the space or distance between the components.

The electronic device of the present disclosure may include electronic components. The electronic components may include passive components, active components, or a combination of the foregoing, such as capacitors, resistors, inductors, varactor diodes, variable capacitors, filters, diodes, transistors, sensors, microelectromechanical system (MEMS) components, liquid crystal chips, etc., but are not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or any combination of the foregoing, but are not limited thereto. The sensors may include, for example, capacitive sensors, optical sensors, electromagnetic sensors, fingerprint sensors (FPS), touch sensors, antennas, or pen sensors, etc., but are not limited to thereto. Electronic components may include dies or LED dies, which may be a die made of silicon (Si), gallium arsenide (GaAs), gallium nitride (GaN), silicon carbide (SiC), sapphire or a glass substrate, but is not limited thereto. In another embodiment, the above-mentioned chips may include a semiconductor packaging component, such as a ball grid array (BGA) packaging component, a chip size package (CSP) component, a flip chip or a 2.5D/3-dimensional (2.5D/3D) semiconductor packaging component, but is not limited thereto. In another embodiment, the chip may be any flip-chip bonding component, such as integrated circuits (ICs), transistors, controlled silicon rectifiers, valves, thin film transistors, capacitors, inductors, variable capacitors, filters, resistors, diodes, microelectromechanical system (MEMS) components, liquid crystal chips, etc., but are not limited thereto. In addition, the chip may include, for example, a diode or a semiconductor chip, but is not limited thereto. The chip may be a known good die (KGD), which may include various electronic components, such as (but not limited to) wires, transistors, circuit boards, etc. Adjacent chips may have different functions, such as integrated circuits, RFICs, and D-RAMs, but are not limited thereto.

Reference will now be made in detail to the exemplary embodiments of the present disclosure, examples of which are illustrated in the accompanying drawings. Whenever possible, the same reference numbers are used in the drawings and descriptions to refer to the same or similar parts. The electronic device may include an imaging device, a laminating device, a display device, a backlight device, an antenna device, a splicing device, a touch electronic device (touch display), a curved electronic device (curved display) or a non-rectangular electronic device (free shape display), but is not limited thereto. The electronic device may include, for example, liquid crystals, light emitting diodes, fluorescences, phosphors, other suitable display medias, or any combination of the foregoing, but are not limited thereto. The display device may be a non-self-luminous display device or a self-luminous display device. The antenna device may be a liquid crystal type antenna device or a non-liquid crystal type antenna device. Sensing device may be a sensing device that senses capacitance, light, heat energy or ultrasonic waves, but is not limited thereto. The splicing device may be, for example, a display splicing device or an antenna splicing device, but is not limited thereto. The electronic device described in the present disclosure may be applied to power modules, semiconductor packaging devices, display devices, light emitting devices, backlight devices, antenna devices, sensing devices or splicing devices, but is not limited thereto. The electronic device may be a bendable or flexible electronic device. The shape of the electronic device may be a rectangular shape, a circular shape, a polygonal shape, a shape with curved edges, or other suitable shapes. It should be noted that the features in various different embodiments may be substituted, rearranged or combined to complete other embodiments without departing from the spirit of the present disclosure. Features in different embodiments may be combined in any way as long as they do not violate the spirit of the disclosure or conflict with each other.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

Herein, the term “height difference” indicates the height difference between the peak of one surface protrusion and the valley of one surface depression, wherein the surface protrusions and the surface depressions are observed on a surface by SEM. The term “roughness” indicates that height differences between the peaks of the surface protrusions and the valleys of the surface depressions are at least 0.1 to 5 μm, wherein the surface protrusions and the surface depressions are observed on the surface by SEM. Determining the “roughness” of a surface may include observing surface undulations at an appropriate magnification using SEM, or a Transmission Electron Microscope (TEM), etc. and comparing the undulations in a unit length (e.g. 10 μm). The term “appropriate magnification” is used here to indicate a magnification at which at least five peaks of surface protrusions and at least five valleys of surface depressions can be observed on at least one surface. Taking reference line L as value 0, the value in the direction from the reference line L to peaks Rp1-Rp5 as a positive value and the value in the direction from the reference line L to valleys Rv1-Rv5 as a negative value. The value difference between peak Rp1 and valley Rv1, value difference between peak Rp2 and valley Rv2, the value difference between peak Rp3 and valley Rv3, the value difference between peak Rp4 and valley Rv4 and the value difference between peak Rp5 and valley Rv5 are calculated. A roughness Rz is obtained by summing the above five value differences and taking an average value thereof. The roughness Rz can be expressed by the following formula, where the reference line L extends in a direction that is perpendicular to the normal direction of the electronic device:

$${R}_{Z} = \frac{1}{5} {\sum }_{i = 1}^{5} {R}_{pi} - {R}_{vi}$$

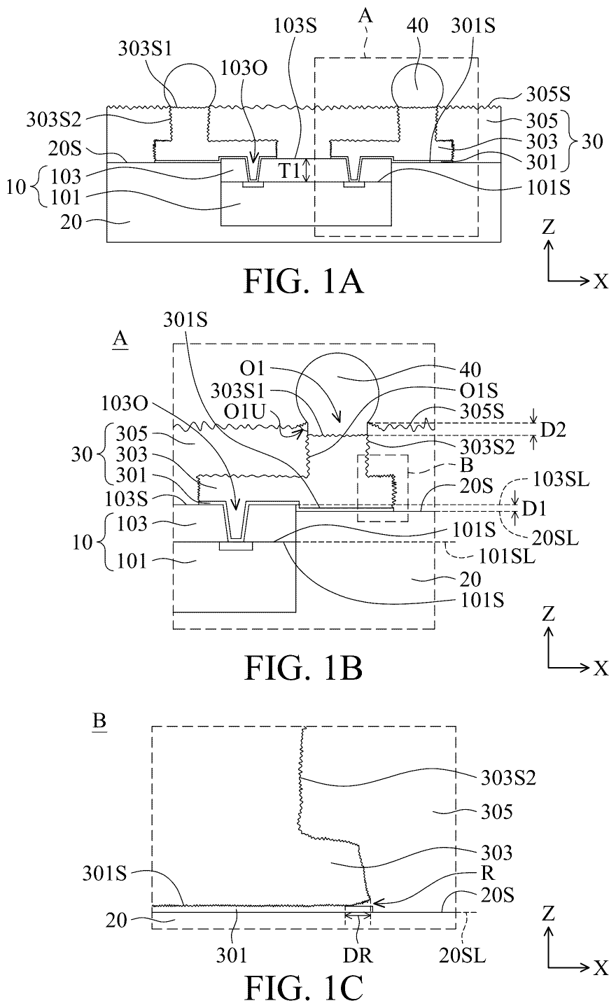

An aspect of the present disclosure is providing an electronic device. FIG. 1A is a schematic cross-sectional view of an electronic device according to an embodiment of the present disclosure. FIG. 1B is an enlarged schematic view of a region A of FIG. 1A. FIG. 1C is an enlarged schematic view of a region B of FIG. 1B. The electronic device of an embodiment of the present disclosure is described below with reference to FIGS. 1A to 1C. The term “schematic cross-sectional view” herein refers to a schematic view intercepted along the normal direction (the Z direction) of the electronic device.

As shown in FIG. 1A, the electronic device of the present disclosure includes an electronic component 10, an encapsulation layer 20 surrounding the electronic component 10, and a circuit structure 30 contacting a first surface 20S of the encapsulation layer 20 and electrically connecting to the electronic component 10. The electronic component 10 may include a chip 101 and a protective layer 103 disposed on an active surface 101S of the chip 101. The protective layer 103 has a second surface 103S away from the active surface 101S. The first surface 20S of the encapsulation layer 20 and the second surface 103S of the protective layer 103 are separated by a first step difference D1, and the first step difference D1 is between 1 and 10 μm.

The electronic component 10 may include the chip 101. In some embodiments, the electronic component 10 may include a passive component, an active component, or a combination of the foregoing. For example, the chip 101 may include a metal oxide semiconductor field effect transistor (MOSFET). The chip 101 in the electronic component 10 may have the active surface 101S. An input/output pad (I/O pad) is formed on the active surface 101S of the chip 101. The chip 101 may output or receive a signal, such as an output voltage or current, via the input/output pads (I/O pads). In some embodiments, the chip 101 may include a chip made of silicon (Si), gallium arsenide (GaAs), gallium nitride (GaN), silicon carbide (SiC), sapphire, or a glass substrate, but the present disclosure is not limited thereto.

The protective layer 103 is provided on the active surface 101S of the chip 101 on which the input/output pads are formed. The protective layer 103 has the second surface 103S away from the active surface 101S and has a pad opening 1030 exposing the input/output pad on the active surface 101S. In some embodiments, the protective layer 103 may include an organic material, an inorganic material, or other suitable insulating materials, such as (but not limited to) epoxy resins, silicon nitrides (SiNx), silicon oxides (SiOx), or any combination thereof, but the present disclosure is not limited thereto. In some embodiments, the protective layer 103 may include a nitride, an oxide, a nitrogen oxide, a perfluoroalkoxyalkane (PFA), a resin, an Ajinomoto build-up film (ABF), a polybenzoxazole (PBO), other suitable materials, or any combination thereof, but the present disclosure is not limited to this. In some embodiments, a thickness T1 of the protective layer 103 may be between 10-30 μm in the Z direction, but the present disclosure is not limited thereto. The protective layer 103 may include a single material layer or a stack of multiple material layers. According to some embodiments, the protective layer 103 may include, for example, at least one organic material layer disposed on the active surface 101S of the chip 101 and at least one inorganic material layer disposed between the active surface 101S of the chip 101 and the organic material layer. The thickness of the inorganic material layer is less than a thickness of the organic material layer in the normal direction (the Z direction) of the electronic device. The ratio of the thickness of the organic material layer to the thickness of the inorganic material layer is greater than or equal to 5 and less than or equal to 35, or is greater than or equal to 7 and less than or equal to 32. The above design may mitigate chip breakage caused by chip cutting, but the disclosure is not limited thereto.

The encapsulation layer 20 surrounds the electronic component 10. The encapsulation layer 20 has the first surface 20S adjacent to the active surface 101S of the chip 101. In the normal direction (the Z direction) of the electronic device, the first surface 20S of the encapsulation layer 20 is spaced apart from the second surface 103S of the protective layer 103 by a first step difference D1, wherein the first step difference D1 is between 1 and 10 μm, that is, 1 μm≤D1≤10 μm. In detail, referring to FIG. 1B, in the schematic cross-sectional view, in a direction (the X direction) that is perpendicular to the normal direction (the Z direction) of the electronic device, the first surface 20S of the encapsulation layer 20 has a virtual extension line 20SL, the second surface 103S of the protective layer 103 has a virtual extension line 103SL, and the active surface 101S of the chip 101 has a virtual extension line 101SL. The virtual extension line 20SL of the first surface 20S is between the virtual extension line 101SL of the active surface 101S of the chip 101 and the virtual extension line 103SL of the second surface 103S of the protective layer 103. In the Z direction, the virtual extension line 20SL of the first surface 20S and the virtual extension line 103SL of the second surface 103S of the protective layer 103 are separated by a first step difference D1, as shown in FIG. 1B. In some embodiments, the first step difference D1 is 1-10 μm, 1-8 μm, 1-5 μm, 2-8 μm, or 2-5 μm. In some embodiments, the encapsulation layer 20 may include an organic material, an inorganic material, or other suitable insulating materials, such as (but not limited to) epoxy resins, silicon nitrides (SiNx), silicon oxides (SiOx), or any combination thereof, but the present disclosure is not limited thereto. In some embodiments, the thickness T1 of the protective layer 103 and the first step difference D1 conform to the following formula: 1/10*T1≤D1≤1/3*T1, but the present disclosure is not limited thereto. In an embodiment, the encapsulation layer 20 surrounds the electronic component 10, and the weathering of the electronic component 10 due to external factors such as water and oxygen can be reduced, or the reliability of the electronic device can be enhanced, but the disclosure is not limited thereto.

The term “surround” herein indicates that in a schematic cross-sectional view, a component A contacts at least a side surface of a component B.

The circuit structure 30 is disposed on the first surface 20S of the encapsulation layer 20. In some embodiments, the circuit structure 30 contacts the first surface 20S of the encapsulation layer 20 and the second surface 103S of the protective layer 103 and electrically connects to the electronic component 10 via the pad opening 1030 of the protective layer 103, as shown in FIG. 1A and FIG. 1B. According to some embodiments, the circuit structure may include at least one conductive layer and at least one insulating layer. Further, the circuit structure 30 may be, for example, a redistribution layer (RDL) structure. The circuit structure 30 may improve a line fan-out area, rearrange the lines, and/or electrically connect other electronic components. For example, a spacing between two adjacent contact pads at an end of the circuit structure contacting the chip is smaller than a spacing between two adjacent contact pads at an end of the circuit structure away from the chip, so that the circuit structure may adjust the line fan-out area, but the disclosure is not limited thereto.

In some embodiments, the circuit structure 30 may include a first conductive layer 301, a first conductive component 303 disposed on the first conductive layer 301, and a first insulating layer 305 disposed on the first conductive layer 301 and the first conductive component 303. The first conductive layer 301 may include seed layers, metals, or a combination thereof. In some embodiments, examples of the metals may include copper (Cu), aluminium (Al), molybdenum (Mo), tungsten (W), gold (Au), chromium (Cr), nickel (Ni), platinum (Pt), titanium (Ti), silver (Ag), tantalum (Ta), metal nitrides, other suitable conductive materials, or any combination thereof, but the disclosure is not limited thereto. In some embodiments, the first conductive layer 301 may be formed on and contact the first surface 20S of the encapsulation layer 20 and the second surface 103S of the protective layer 103. The first conductive layer 301 may improve an adhesion between subsequently formed films or layers and the encapsulation layer 20 or the protective layer 103, but the disclosure is not limited thereto. In some embodiments, a thickness of the first conductive layer 301 may be between 0.2-2 μm. The first conductive layer 301 may be, for example, a seed layer, but the disclosure is not limited thereto. In some embodiments, the first conductive layer 301 may be a single layer or multiple layers. In some embodiments, the first conductive layer 301 may extend from the first surface 20S and the second surface 103S into the pad opening 1030 of the protective layer 103 to electrically connect the input/output pads on the active surface 101S of the chip 101. In other words, the first conductive layer 301 is formed on a sidewall of the pad opening 1030 as shown in FIG. 1A and FIG. 1B, but the disclosure is not limited thereto.

In some embodiments, the first conductive component 303 is formed on a conductive layer surface 301S of the first conductive layer 301. In some embodiments, an accommodation space R is between the first conductive layer 301 and the first conductive component 303, as shown in FIG. 1C. In some embodiments, the accommodation space R has a depth DR along a direction (the X direction) perpendicular to the Z direction, and the depth DR is 1-10 μm, 0.1-5 μm or 0.5-3 μm, but the disclosure is not limited thereto. In an embodiment, the electronic device includes the structure described above, and subsequently formed films or layers may extend into the accommodation space R. For example, a portion of the first insulating layer 305 may extend into the accommodation space R, or it may be filled into the accommodation space R, thereby enhancing the adhesion between the films or layers of the electronic device, but the disclosure is not limited thereto. In some embodiments, the first conductive component 303 may include a metal trace extending in the X direction. In some embodiments, the first conductive component 303 may further include a metal trace extending in the X direction and a metal trace extending in the Z direction. The circuit structure 30 may include stacking the at least one first conductive layer 301 and the at least one first conductive component 303 along the Z direction.

The first conductive component 303 has a conductive component top surface 303S1, an conductive component bottom surface (not shown) adjacent to the conductive layer surface 301S of the first conductive layer 301, and a conductive component side surface 303S2 connecting the conductive component top surface 303S1 and the conductive component bottom surface. The conductive component top surface 303S1 is away from the conductive layer surface 301S of the first conductive layer 301. In some embodiments, the conductive component top surface 303S1, the conductive component bottom surface, and/or the conductive component side surface 303S2 of the first conductive component 303 have roughness. Specifically, the conductive component top surface 303S1, the conductive component bottom surface, and/or the conductive component side surface 303S2 may include a microstructure formed by a plurality of surface protrusions and a plurality of surface depressions. In some embodiments, there is a first height difference between the peak of a surface protrusion and the valley of a surface depression in the conductive component top surface 303S1, the conductive component bottom surface, and/or the conductive component side surface 303S2. The first height difference is 0.1-5 μm, 0.2-4 μm, or 0.5-3 μm. The term “first height difference” herein indicates the height difference between the highest peak of the surface protrusions and the lowest valley of the surface depressions in the conductive component top surface 303S1, the conductive component bottom surface, and/or the conductive component side surface 303S2. The first conductive component 303 may include seed layers, metals, or a combination thereof. In some embodiments, examples of the metals may include copper (Cu), aluminium (Al), molybdenum (Mo), tungsten (W), gold (Au), chromium (Cr), nickel (Ni), platinum (Pt), titanium (Ti), silver (Ag), tantalum (Ta), other suitable metallic materials, or any combination thereof, but the present disclosure is not limited thereto. In some embodiments, the first conductive component 303 may include the same or a different material as the first conductive layer 301.

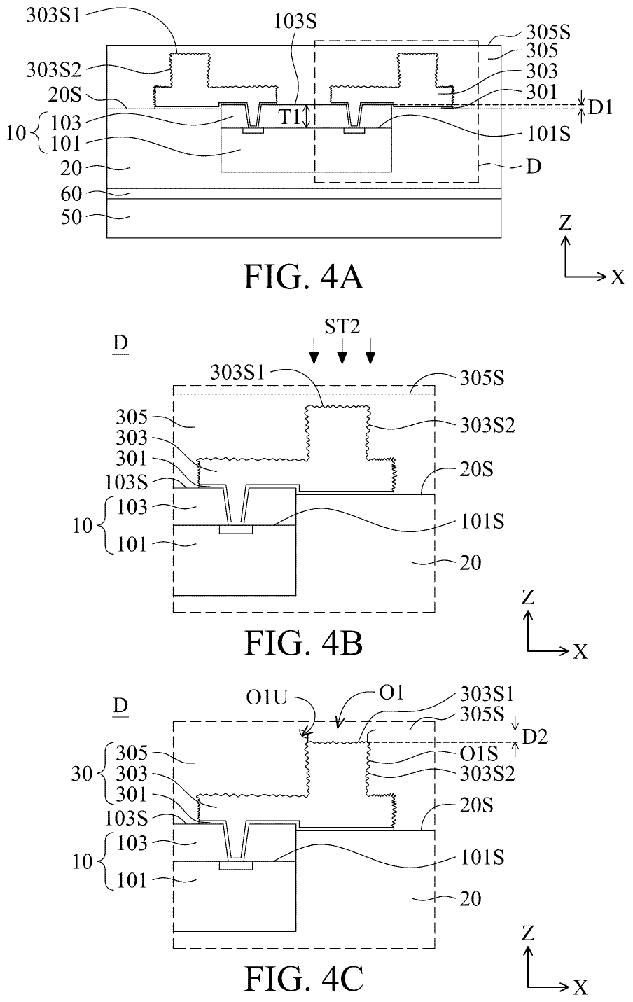

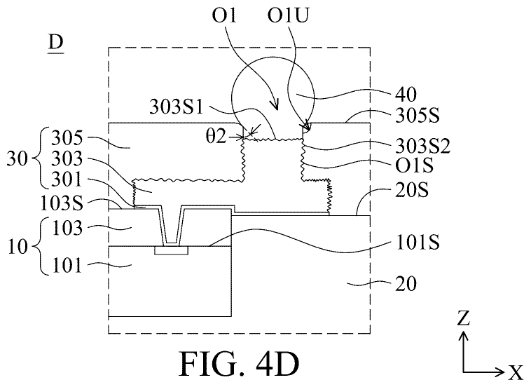

The first insulating layer 305 may be formed on the first conductive layer 301 and the first conductive component 303 and have an insulating layer surface 305S. The insulating layer surface 305S is away from the second surface 103S of the protective layer 103 and the first surface 20S of the encapsulation layer 20. The first insulating layer 305 surrounds the first conductive layer 301 and the first conductive component 303 and covers the conductive component side surface 303S2 of the first conductive component 303. According to some embodiments, the first insulating layer 305 may cover at least a portion of the conductive component top surface 303S1 of the first conductive component 303. That is, the first insulating layer 305 may expose at least a portion of the conductive component top surface 303S1. In detail, the first insulating layer 305 has a first opening O1, the first conductive component 303 is disposed in the first opening O1, and the first opening O1 exposes at least a portion of the conductive component top surface 303S1 of the first conductive component 303, as shown in FIG. 1A and FIG. 1B. The first opening O1 may have a sidewall O1S. A connection part O1U may be located between the sidewall O1S of the first opening O1 and the insulating layer surface 305S of the first insulating layer 305. That is, the connection part O1U connects the sidewall O1S of the first opening O1 and the insulating layer surface 305S of the first insulating layer 305. In some embodiments, the connection part O1U may be a corner, the angle of the corner may be a right, obtuse, leading or acute angle. In some embodiments, the angle of the connection part O1U may be between 15° to 145°. In other words, the angle between the sidewall O1S and the insulating layer surface 305S of the first insulating layer 305 may be between 45° to 145°. In some embodiments, please refer to FIG. 4D, the connection part O1U may have a curved profile. When the connection part O1U has a curved profile, the risk of cracking of subsequently formed components may be reduced, but the present disclosure is not limited thereto.

In some embodiments, the insulating layer surface 305S of the first insulating layer 305 may have a roughness. Specifically, the insulating layer surface 305S may include a microstructure formed by a plurality of surface protrusions and a plurality of surface depressions. In some embodiments, a second height difference is between the peak of a surface protrusion and the valley of a surface depression of the insulating layer surface 305S, and the second height difference is 0.1-5 μm, 0.2-4 μm, or 0.5-5 μm. The term “second height difference” herein indicates a height difference between the highest peak of the surface protrusions and the lowest valley of the surface depressions of the insulating layer surface 305S. In some embodiments, the roughness of the conductive component top surface 303S1 may be greater than the roughness of the insulating layer surface 305S. In some embodiments, the conductive component top surface 303S1 of the first conductive component 303 is between the insulating layer surface 305S of the first insulating layer 305 and the first surface 20S of the encapsulation layer 20. In some embodiments, a second step difference D2 is between the conductive component top surface 303S1 of the first conductive component 303 and the insulating layer surface 305S of the first insulating layer 305 along the normal direction (the Z direction) of the electronic device. The second step difference D2 is 1-15 μm, 3-12 μm, 5-10 μm, or 6-9 μm. The term “the second segment difference D2” used herein indicates a distance between the connection part O1U between the insulating layer surface 305S and the sidewall O1S and the conductive component top surface 303S1 of the first conductive component 303.

In some embodiments, at least a portion of the first insulating layer 305 will fill the microstructure of the conductive layer surface 301S of the first conductive layer 301. In other words, at least a portion of the first insulating layer 305 will fill at least one surface depression of the conductive layer surface 301S of the first conductive layer 301. In some embodiments, at least a portion of the first insulating layer 305 will fill the accommodation space R. In some embodiments, at least a portion of the first insulating layer 305 will fill at least one surface depression of the conductive component top surface 303S1 and/or the conductive component side surface 303S2 of the first conductive component 303. In some embodiments, the first insulating layer 305 may include an organic material, an inorganic material, a combination of the foregoing, or other suitable insulating materials, such as (but not limited to) polymers, epoxys, silicon nitrides (SiNₓ), silicon oxides (SiOₓ), aluminium oxides (Al₂O₃), titanium dioxides (TiO₂) or any combination thereof, but the present disclosure is not limited thereto. In some embodiments, the first insulating layer 305 may include silica particles dispersed in an organic material, such as an epoxy resin, wherein the silica particles may have a particle size ranging from 0.1 to 20 μm. For example, at least a portion of the silica particles, or a portion of the organic material, such as an epoxy resin, are filled into the depressions of the conductive layer surface 301S of the first conductive layer 301 and the depressions of the conductive component top surface 303S1 of the first conductive component 303, thereby enhancing an adhesion between other films or layers, but the present disclosure is not limited thereto.

In some embodiments, the electronic device may further include a connecting component 40 that overlaps the first conductive component 303. In some embodiments, a portion of the connecting component 40 may be filled into the first opening O1 of the first insulating layer 305 and electrically connected to the conductive component top surface 303S1 of the first conductive component 303 exposed by the first opening O1 as shown in FIG. 1A and FIG. 1B. In some embodiments, the sidewall O1S of the first opening O1 surrounds the portion of the connecting component 40 in the first opening O1, as shown in FIG. 1A and FIG. 1B. In some embodiments, the connecting component 40 may include a solder ball, a solder paste, such as a tin paste, a tin ball, a copper post (pillar), or other suitable conductive materials and structures, but the present disclosure is not limited thereto. In embodiments that the connecting component 40 includes a solder ball, the connecting component 40 has a contact point with the connection part O1U. There is an angle between the tangent line through the contact point and the sidewall O1S. The angle may be angle θ2 and it may be greater than or equal to 15 degrees and less than or equal to 50 degrees. In some embodiments, an intermediate layer (not shown) may be formed between the connecting component 40 and the first conductive component 303. In some embodiments, the intermediate layer has a thickness of between 3-5 μm in the Z direction. In some embodiments, the intermediate layer may have an intermediate layer surface. The intermediate layer surface is adjacent to the connecting component 40 and may have a roughness. In some embodiments, the intermediate layer surface is a concave surface. In an embodiment, the electronic device includes the structure described above, and there is a second step difference D2 between the conductive component top surface 303S1 of the first conductive component 303 and the insulating layer surface 305S of the first insulating layer 305. A portion of the connecting component 40 is disposed in the first opening O1 of the first insulating layer 305 and is in contact with the first conductive component 303. The adhesion between the connecting component 40 and the first conductive component 303 may be improved, but the present disclosure is not limited thereto.

The electronic device having the structure described in the present disclosure can improve an adhesion between components in the electronic device at least by the first step difference D1 and the roughness of the conductive layer surface 301S, the conductive component top surface 303S1, the conductive component side surface 303S2, and the insulating layer surface 305S. The risk of signal or power paths breaking in the electronic device can be reduced, thereby increasing the reliability of the electronic device.

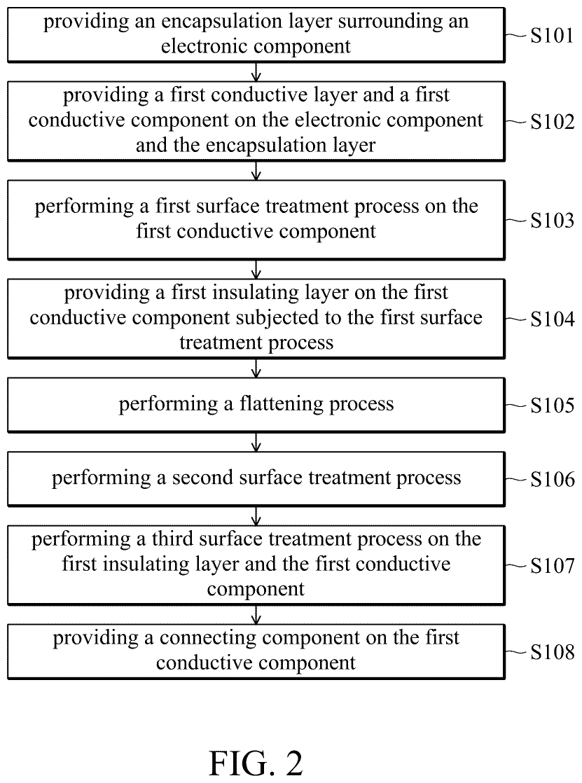

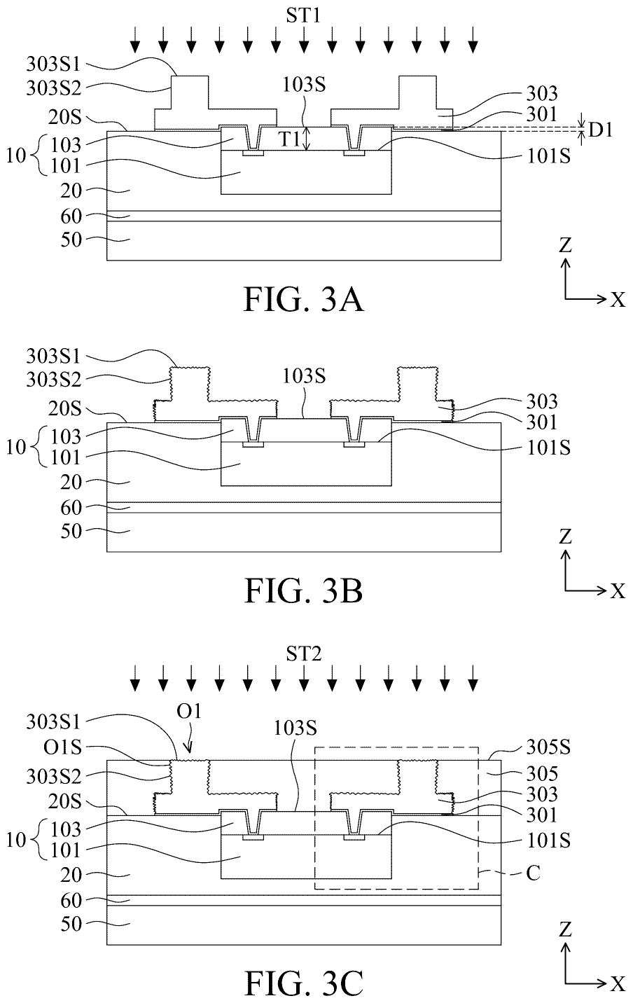

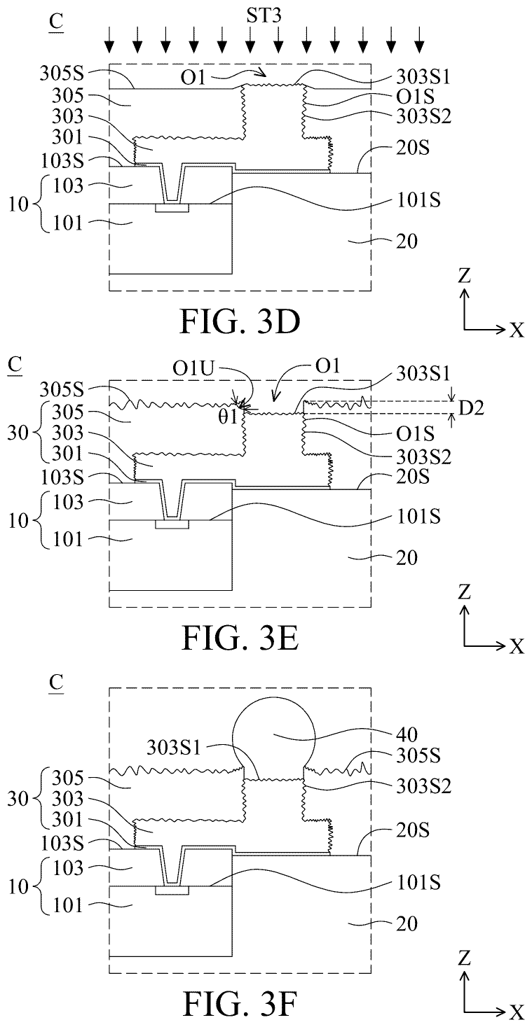

Another aspect of the present disclosure provides a method of manufacturing an electronic device. FIG. 2 is a flowchart of a method of manufacturing an electronic device according to an embodiment of the present disclosure. As shown in FIG. 2, the method of manufacturing the electronic device of the present disclosure may include: a step S101 of providing an encapsulation layer surrounding an electronic component; a step S102 of providing a first conductive layer and a first conductive component on the electronic component and the encapsulation layer; a step S103 of performing a first surface treatment process on the first conductive component; a step S104 of providing a first insulating layer on the first conductive component subjected to the first surface treatment process; a step S105 of performing a flattening process; and a step S106 of performing a second surface treatment process. In some embodiments, the method of manufacturing the electronic device of the present disclosure may further include a step S108 of providing a connecting component on the first conductive component after step S106. In some embodiments, the method of manufacturing the electronic device of the present disclosure may further include a step S107 of performing a third surface treatment process on the first insulating layer and the first conductive component after step S106. In some embodiments, the method of manufacturing the electronic device of the present disclosure may further include a step S107 of performing a third surface treatment process on the first insulating layer and the first conductive component and a step S108 of providing a connecting component on the first conductive component after step S106, wherein step S107 is performed between step S106 and step S108. FIGS. 3A to 3F are schematic cross-sectional views of semi-finished products of an electronic device at various stages of a method of manufacturing an electronic device according to an embodiment of the present disclosure. In order to more clearly illustrate the manufacturing method of the present disclosure, FIG. 3D to FIG. 3F are illustrated with an enlarged schematic view of a region C of FIG. 3C. Steps S101 to step S108 of the manufacturing method of the electronic device of an embodiment of the present disclosure are described below with FIG. 2 and FIGS. 3A to 3F.

In step S101, the electronic component 10 includes a chip 101 and a protective layer 103 covering an active surface 101S of the chip 101. Input/output pads on the active surface 101S of the chip 101 are exposed via a pad opening 1030 of the protective layer 103. In some embodiments, the protective layer 103 has a thickness T1 in the Z direction. The encapsulation layer 20 surrounding the electronic component 10 has a first surface 20S. A second surface 103S of the protective layer 103 is higher than the first surface 20S of the encapsulation layer 20. The second surface 103S of the protective layer 103 and the first surface 20S of the encapsulation layer 20 are separated by a first step difference D1 in the Z direction. In some embodiments, the first step difference D1 may be between 1-10 μm, 1-8 μm, 1-5 μm, 2-8 μm, or 2-5 μm. The thickness T1 of the protective layer 103 and the first step difference D1 conform to the following formula: 1/10*T1≤D1≤1/3*T1.

Step S102 of providing the first conductive layer and the first conductive component on the electronic component may include disposing the electronic component 10 surrounded by the encapsulation layer 20 on a carrier substrate 50 on which a release layer 60 is formed; forming the first conductive layer 301 on the second surface 103S of the protective layer 103 of the electronic component 10 and the first surface 20S of the encapsulation layer 20; and forming the first conductive component 303 on the first conductive layer 301. The first conductive layer 301 is between the first conductive component 303 and the electronic component 10 and electrically connects the first conductive component 303 and the electronic component 10. Specifically, the first conductive component 303 may be electrically connected to the input/output pad on the active surface 101S of the chip 101 exposed via the pad opening 1030 of the first conductive layer 301. In some embodiments, a portion of the first conductive component 303 is filled into the pad opening 1030 and disposed between the first conductive layer 301 and the protective layer 103, but the present disclosure is not limited thereto. The release layer 60 may include an adhesive material, such as adhesive materials that can be debonded by applications of laser, light or heat, but the present disclosure is not limited thereto.

After the first conductive layer 301 and the first conductive component 303 are formed, a first surface treatment process ST1 is performed on the first conductive component 303 in step S103, as shown in FIG. 3A. The conductive component top surface 303S1 and the conductive component side surface 303S2 of the first conductive component 303 subjected to the first surface treatment process ST1 may have roughness, as shown in FIG. 3B. The roughness of the conductive layer surface 301S, the conductive component top surface 303S1, and the conductive component side surface 303S2 have been described above, so it will not be repeated here. Methods used in the first surface treatment process ST1 include a plasma treatment method, a grinding method, a dry etching method, a wet etching method, or other suitable methods, but the present disclosure is not limited thereto.

In step S104, a first insulating layer 305 surrounding the first conductive layer 301 and the first conductive component 303 is provided on the first conductive component 303 subjected to the first surface treatment process ST1. The first insulating layer 305 covers the conductive component top surface 303S1 of the first conductive component 303. A flattening process is then performed on the first insulating layer 305 in step S105. Methods used in the flattening process include a grinding method, but the present disclosure is not limited thereto. In step S105, the flattening process is performed until the first conductive component 303 is exposed. That is, the structure obtained after step S105 may include the first insulating layer 305 which is subjected to the flattening process and exposes the conductive component top surface 303S1 of the first conductive component 303, as shown in FIG. 3C, but the present disclosure is not limited thereto.

In step S106, a second surface treatment process ST2 is performed on the first insulating layer 305. The second surface treatment process ST2 in step S106 is described below using the structure shown in FIG. 3C as an example. In the embodiment, the second surface treatment process ST2 may include performing a plasma etching process on the entire insulating layer surface 305S of the first insulating layer 305 and on the exposed conductive component top surface 303S1 of the first conductive component 303. In the embodiment, after the second surface treatment process ST2, the first conductive component 303 slightly protrudes above the first insulating layer 305, and the resulting structure can be referred to FIG. 3D. In the embodiment, the method of manufacturing the electronic device of the present disclosure may further include, after step S106, performing step S107 on the first insulating layer 305 and the first conductive component 303 subjected to the second surface treatment process ST2, as shown in FIG. 3D, to form the circuit structure 30 as shown in FIG. 3E. Step S107 includes a third surface treatment process ST3. In some embodiments, the third surface treatment process ST3 may include a chemical etching process, but the present disclosure is not limited thereto. In the third surface treatment process ST3, a portion of the first conductive component 303 in the first opening O1 is removed, thereby forming a second step difference D2 between the conductive component top surface 303S1 of the first conductive component 303 and the insulating layer surface 305S of the first insulating layer 305 in the Z direction. In some embodiments, the second step difference D2 may be between 1-15 μm, 3-12 μm, 5-10 μm, or 6-9 μm. The insulating layer surface 305S subjected to the third surface treatment process ST3 may have a roughness. In some embodiments, the roughness of the first conductive component 303 subjected to the first surface treatment process ST1 may be greater than the roughness of the first insulating layer 305 subjected to the third surface treatment process ST3, but the present disclosure is not limited thereto. Other specific structures of the circuit structure 30 are as described above and will therefore not be repeated here.

The method of manufacturing an electronic device of the present disclosure may further include step S108 of providing a connecting component 40 on the circuit structure 30, and the resulting structure is as shown in FIG. 3F. A portion of the connecting component 40 may be filled into the first opening O1 of the first insulating layer 305. The connecting component 40 may be electrically connected to the conductive component top surface 303S1 of the first conductive component 303 exposed via the first opening O1. Accordingly, the electronic device of the present disclosure may be electrically connected to an external device or other electronic devices through the connecting component 40.

FIGS. 4A to 4D are schematic cross-sectional views of semi-finished products of an electronic device at various stages of a method of manufacturing an electronic device according to another embodiment of the present disclosure. In order to more clearly illustrate the manufacturing method of the present disclosure, FIGS. 4B to 4D are illustrated with an enlarged schematic view of a region D of FIG. 4A. Specifically, FIGS. 4A to 4D disclose an embodiment in which, in the structure obtained in step S105, the first insulating layer 305 still covers the conductive component top surface 303S1 of the first conductive component 303. In this embodiment, steps S101 to S105 are the same as described above, except that the conductive component top surface 303S1 is not exposed by the flattening process in step S105, and therefore these steps are not repeated herein. Steps S106 and step S108 of the method of manufacturing an electronic device of another embodiment of the present disclosure are described below in conjunction with FIG. 2 and FIGS. 4A to 4D.

In step S106, the second surface treatment process ST2 is performed on the first insulating layer 305. The second surface treatment process ST2 in step S106 is described below using the structure shown in FIGS. 4A to 4C as an example. In the embodiment, the second surface treatment process ST2 includes performing a partial plasma etching process on a portion of the first insulating layer 305 on the conductive component top surface 303S1 of the first conductive component 303 to form a first opening O1 exposing the conductive component top surface 303S1 of the first conductive component 303. The circuit structure 30 obtained by step S106 has a second step difference D2 between the conductive component top surface 303S1 of the first conductive component 303 and the insulating layer surface 305S of the first insulating layer 305 in the Z direction. In some embodiments, the second step difference D2 may be between 1-15 μm, 3-12 μm, 5-10 μm, or 6-9 μm. Other specific structures of the circuit structure 30 are as described above and will therefore not be repeated here.

In some embodiments, the method of manufacturing the electronic device of the present disclosure may further include performing, for example, a plasma etching process on the first insulating layer 305. Therefore, the connection part O1U between the insulating layer surface 305S of the first insulating layer 305 and the sidewall O1S has a curved profile, but the present disclosure is not limited thereto.

The method of manufacturing the electronic device of the present disclosure may further include a step S108 of providing a connecting component 40 on the circuit structure 30, and the resulting structure is as shown in FIG. 4D. A portion of the connecting component 40 may be filled into the first opening O1 of the first insulating layer 305. The connecting component 40 may be electrically connected to the conductive component top surface 303S1 of the first conductive component 303 exposed via the first opening O1. In some embodiments, a portion of the connecting component 40 is disposed on the first insulating layer 305. The electronic device of the present disclosure may be electrically connected to an external device or other electronic devices through the connecting component 40. The external device includes a circuit board, an ABF carrier structure, a glass carrier structure, an encapsulated structure, or other suitable external devices, but the present disclosure is not limited thereto.

The electronic device manufactured according to the method of manufacturing an electronic device of the present disclosure above may improve an adhesion between components in the electronic device at least by the first step difference D1 and the roughness of the conductive layer surface 301S, the conductive component top surface 303S1, the conductive component side surface 303S2, and the insulating layer surface 305S. The risk of signal or power paths breaking in the electronic device can be reduced, thereby increasing the reliability of the electronic device.

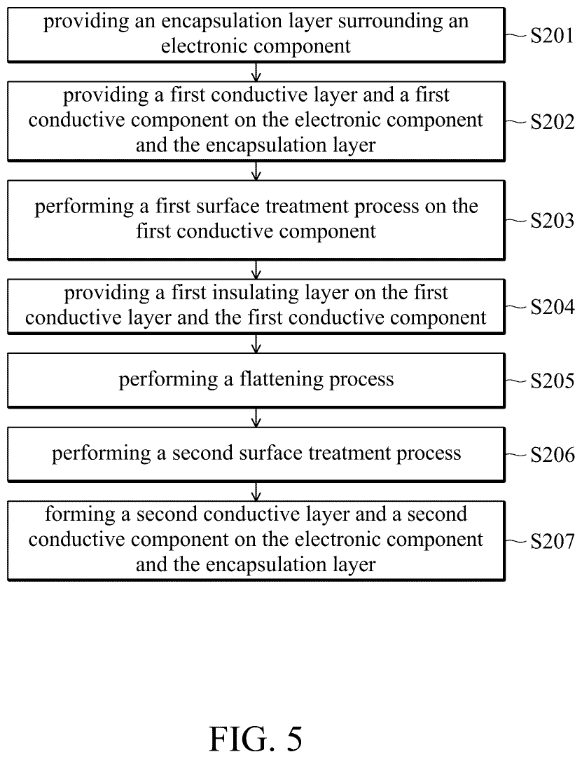

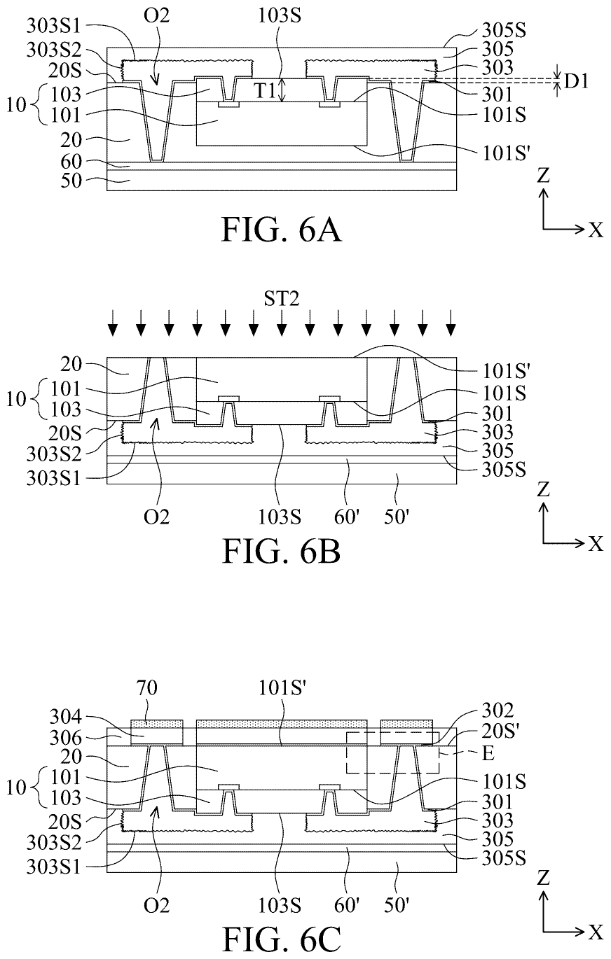

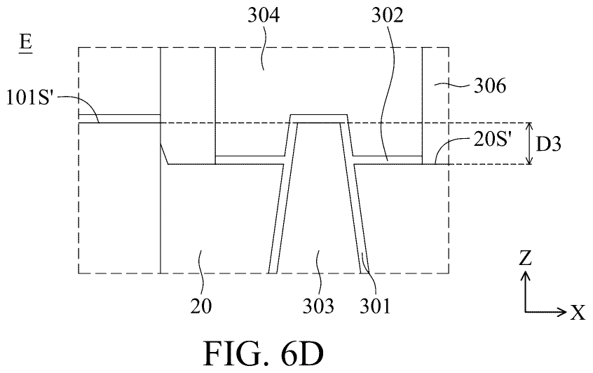

Another aspect of the present disclosure provides a method of manufacturing an electronic device. FIG. 5 is a flowchart of a method of manufacturing an electronic device according to an embodiment of the present disclosure. As shown in FIG. 5, the method of manufacturing the electronic device of the present disclosure may include: a step S201 of providing an encapsulation layer surrounding an electronic component; a step S202 of providing a first conductive layer and a first conductive component on the electronic component and the encapsulation layer; a step S203 of performing a first surface treatment process on the first conductive component; a step S204 of providing a first insulating layer on the first conductive layer and the first conductive component; a step S205 of performing a flattening process; a step S206 of performing a second surface treatment process; and a step S207 of forming a second conductive layer and a second conductive component on the electronic component and the encapsulation layer. FIGS. 6A to 6C are schematic cross-sectional views of semi-finished products of an electronic device at various stages of a method of manufacturing an electronic device according to another embodiment of the present disclosure. FIG. 6D is an enlarged schematic view of a region E in FIG. 6C. Step S201 to step S207 of the method of manufacturing the electronic device of an embodiment of the present disclosure are described below with FIG. 5 and FIGS. 6A to 6D.

Steps S201 to S204 are substantially the same as steps S101 to S104 except that a second opening O2 is further formed in the encapsulation layer 20 in step S201, and a portion of the first conductive layer 301 and the first conductive component 303 are formed in the second opening O2 in step S202. Therefore, steps S201 to S204 will not be repeated herein. The structure formed by steps S201 to S204 is shown in FIG. 6A.

Step S205 includes disposing the structure shown in FIG. 6A on a carrier substrate 50′ on which a release layer 60′ is formed; removing the release layer 60′ and the carrier substrate 50′ to expose the encapsulation layer 20 and the first conductive layer 301, and the first conductive component 303 formed in the second opening O2; and performing a flattening process on the first conductive layer 301, the first conductive component 303, and the encapsulation layer 20 to expose a chip back surface 101S′ of the chip 101 opposite the active surface 101S, and the resulting structure may be referred to in FIG. 6B. The release layer 60′ may be substantially the same as the release layer 60, and therefore will not be described herein. In detail, a conductive material, such as a portion of the first conductive component 303, may be filled in the second opening O2 of the encapsulation layer 20 to form a conductive via hole structure. The chip 101 may be electrically connected to an external component by the conductive via hole structures. In some embodiments, these conductive via hole structures may enhance a heat dissipation capability of the electronic device, but the present disclosure is not limited thereto.

A second surface treatment process ST2 is performed on the encapsulation layer 20 in step S206, as shown in FIG. 6B. The second surface treatment process ST2 may include performing a plasma etching process on the entire encapsulation layer 20 and the exposed first conductive layer 301, the exposed first conductive component 303, and the chip back surface 101S′ of the chip 101. In this embodiment, after the second surface treatment process ST2, another surface 20S′ of the encapsulation layer 20 opposite the first surface 20S is formed, and the first conductive component 303 slightly protrudes above the encapsulation layer 20. That is, in some embodiments, the first conductive component 303 is higher than the other surface 20S′ of the encapsulation layer 20 in the Z direction. Therefore, the other surface 20S′ of the encapsulation layer 20 and the first conductive component 303 may be separated by a third step difference D3 in the Z direction, and the resulting structure may be referred to in FIG. 6D. In some embodiments, the third step difference D3 is greater than or equal to 0.2 μm and less than or equal to 5 μm. When a surface of the conductive material in the conductive via hole structure, such as the first conductive component 303, protrudes above the other surface 20S′ of the encapsulation layer 20, the contact area with subsequently formed films or layers can be improved, thereby enhancing an adhesion between different films or layers, but the present disclosure is not limited thereto.

A second conductive layer 302, a second conductive component 304, and a second insulating layer 306 are formed on the electronic component 10 and the encapsulation layer 20 in step S207 to obtain the circuit structure 30. In some embodiments, the method of manufacturing the electronic device of the present disclosure may further include performing a second surface treatment process ST2 on the second insulating layer 306, followed by performing the third surface treatment process ST3 on the second conductive component 304 to form a step difference between the second insulating layer 306 and the second conductive component 304. The step difference above may be similar to the second step difference D2, wherein the step difference is between 1-15 μm, but the present disclosure is not limited thereto. The method of manufacturing the electronic device further includes forming a connecting component 70 (structure thereof is as shown in FIG. 6C) on the second conductive component 304 of the circuit structure 30. A portion of the connecting component 70 is disposed in an opening of the second insulating layer 306 and is in contact with the second conductive component 304. The connecting component 70 may be similar to the connecting component 40, so it will not be repeated here.

The electronic device manufactured according to the method of manufacturing an electronic device of the present disclosure above can improve an adhesion between components in the electronic device at least by: the third step difference D3, the first conductive layer 301 and a first conductive component 303 having rough surfaces and a step difference between the first conductive component 303 and another surface 20S′ of the encapsulation layer 20 and a step difference between the second insulating layer 306 and the second conductive component 304 in the Z direction. The risk of signal or power paths breaking in the electronic device can be reduced, thereby increasing the reliability of the electronic device.

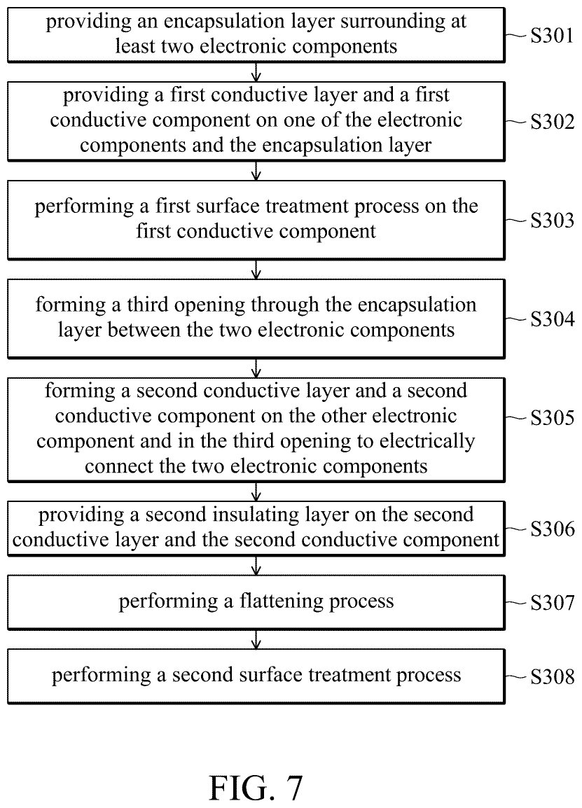

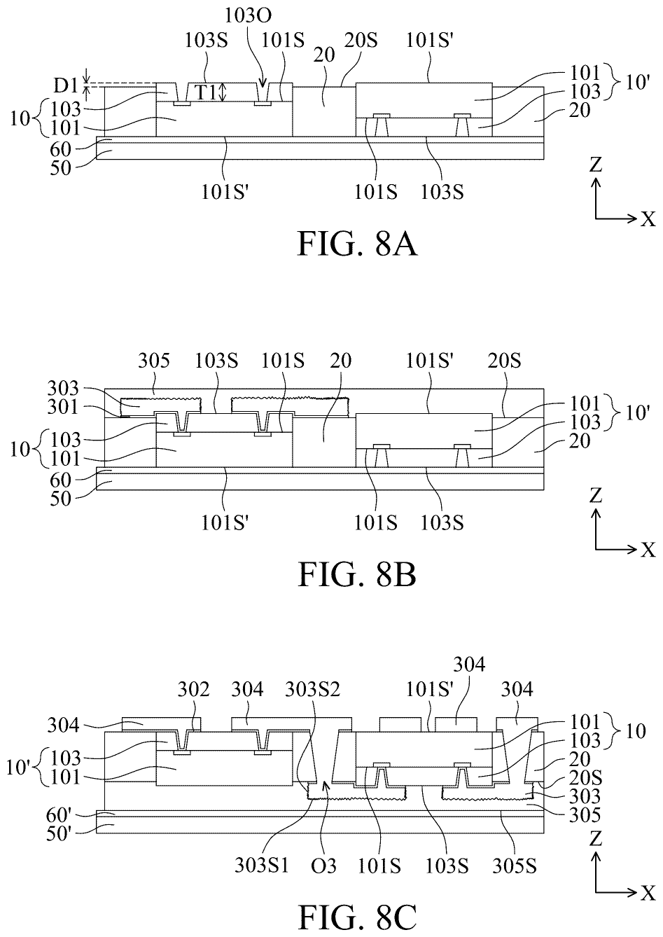

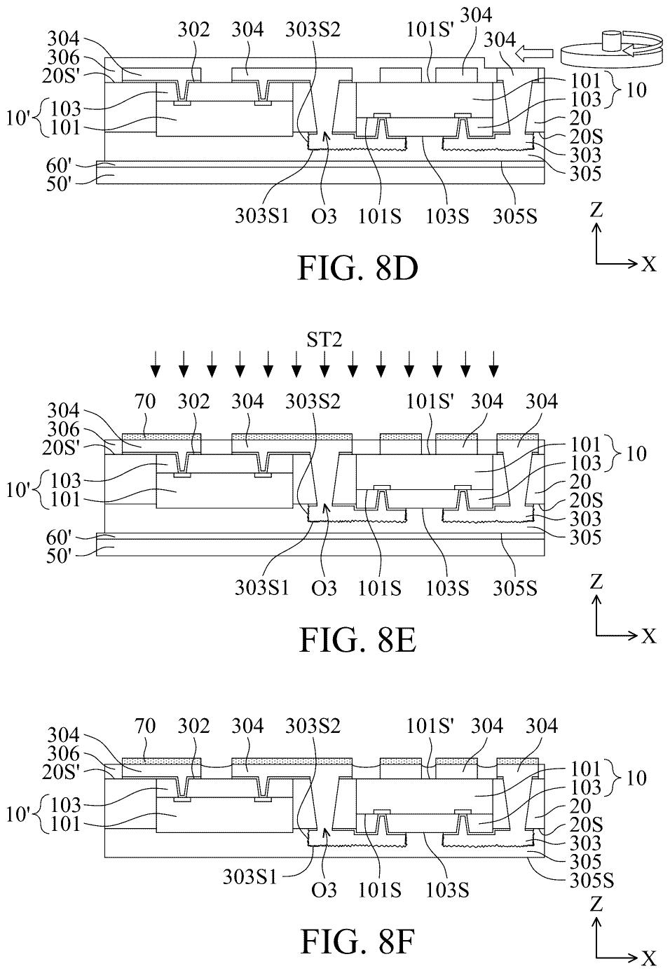

Another aspect of the present disclosure provides a method of manufacturing an electronic device. FIG. 7 is a flowchart of a method of manufacturing an electronic device according to an embodiment of the present disclosure. As shown in FIG. 7, the method of manufacturing the electronic device of the present disclosure may include the following steps. Step S301 provides an encapsulation layer surrounding at least two electronic components. Step S302 provides a first conductive layer and a first conductive component on one of the electronic components and the encapsulation layer. Step S303 performs a first surface treatment process on the first conductive component. Step S304 forms a third opening through the encapsulation layer between the two electronic components. Step S305 involves forming a second conductive layer and a second conductive component on the other electronic component and in the third opening to electrically connect the two electronic components. Step S306 involves providing a second insulating layer on the second conductive layer and the second conductive component. Step S307 involves performing a flattening process. Step S308 involves performing a second surface treatment process. FIGS. 8A to 8F are schematic cross-sectional views of semi-finished products of an electronic device at various stages of a method of manufacturing an electronic device according to another embodiment of the present disclosure. Step S301 to step S308 of the method of manufacturing the electronic device of an embodiment of the present disclosure are described below with FIG. 7 and FIGS. 8A to 8F.

Step S301 includes providing an electronic component 10 and an electronic component 10′ on a carrier substrate 50 on which a release layer 60 is formed. The electronic component 10 includes a chip 101 and a protective layer 103. The chip 101 includes an active surface 101S and a chip back surface 101S′ opposite each other. The protective layer 103 covers the active surface 101S of the chip 101. The electronic component 10′ has substantially the same structure as the electronic component 10, and is therefore not described herein. In some embodiments, the electronic component 10 is provided on the release layer 60 in a manner that the chip 101 is disposed between the release layer 60 and the protective layer 103, and the electronic component 10′ is provided on the carrier substrate 50 in a manner that the protective layer 103 is disposed between the release layer 60 and the chip 101, but the present disclosure is not limited thereto. In some embodiments, the electronic component 10 and the electronic component 10′ may be provided on the carrier substrate 50 in the same manner. The encapsulation layer 20 surrounds the electronic component 10 and the electronic component 10′. In some embodiments, in the Z direction, the protective layer 103 has a thickness T1. The second surface 103S of the protective layer 103 of the electronic component 10 is higher than the first surface 20S of the encapsulation layer 20. The chip back surface 101S′ of the chip 101 of the electronic component 10′ is higher than or at the same level as the first surface 20S of the encapsulation layer 20, as shown in FIG. 8A. In the Z direction, the second surface 103S of the protective layer 103 of the electronic component 10 and the first surface 20S of the encapsulation layer 20 are separated by a first step difference D1. The first step difference D1 is between 1-10 μm, 1-8 μm, 1-5 μm, 2-8 μm, or 2-5 μm. In some embodiments, the thickness T1 of the protective layer 103 of the electronic component 10 and the first step difference D1 conform to the following formula: 1/10*T1≤ D1≤1/3*T1. The input/output pads on the active surface 101S of the chip 101 of the electronic component 10 are exposed via the pad opening 1030 of the protective layer 103 of the electronic component 10.

Steps S302 to S303 are substantially the same as steps S102 to S103, so they will not be repeated here.

Step S304 may include first forming the first insulating layer 305 on the first conductive layer 301 and the first conductive component 303 on the electronic component 10 and on the chip back surface 101S′ of the chip 101 of the electronic component 10′ to form a structure as shown in FIG. 8B; disposing the structure as shown in FIG. 8B on a carrier substrate 50′ on which a release layer 60′ is formed; removing the release layer 60′ and the carrier substrate 50′; and forming a third opening O3 through the encapsulation layer 20 between the electronic components 10 and 10′.

Step S305 including forming a second conductive layer 302 in the pad opening 1030 of the electronic component 10′ to electrically connect the input/output pad on the active surface 101S of the chip 101 (for example, the input/output pad may be, such as one of three ends of a gate, a drain, or a source); and forming a second conductive component 304 on the second conductive layer 302, in the third opening O3, and on the chip back surface 101S′ of the chip 101 of the electronic component 10. The structure obtained in step S305 is as shown in FIG. 8C. In the structure obtained in step S305, the electronic component 10 and the electronic component 10′ are electrically connected through the first conductive layer 301, the second conductive layer 302, the first conductive component 303, and the second conductive component 304.

In step S306, the second insulating layer 306 is provided on the second conductive layer 302 and the second conductive component 304. In step S307, a flattening process is performed on the second insulating layer 306 until the second conductive component 304 is exposed, as shown in FIG. 8D.

In step S308, a second surface treatment process ST2 is performed on the second insulating layer 306. In some embodiments, a photoresist layer (not shown) may be formed on the second conductive component 304 to protect the second conductive component 304 before performing the second surface treatment process ST2, as shown in FIG. 8E. The structure of the electronic device obtained after the second surface treatment process ST2 of step S308 is shown as in FIG. 8F. As can be seen from FIG. 8F, after the second surface treatment process ST2 of step S308, the second conductive component 304 will protrude above the second insulating layer 306. That is, a gap is formed between the second conductive component 304 and the second insulating layer 306 in the Z direction. According to some embodiments, a surface of the second insulating layer 306 has a curved profile.

The electronic device manufactured according to the method of manufacturing an electronic device of the present disclosure above may improve an adhesion strength between components in the electronic device at least by: the first step difference D1, the first conductive layer 301 and a first conductive component 303 having rough surfaces and a step difference between the second insulating layer 306 and the second conductive component 304. The risk of signal or power paths breaking in the electronic device can be reduced, thereby increasing the reliability of the electronic device.

Although embodiments of the present disclosure and the advantages thereof have been disclosed as described above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. An electronic device, comprising:
an electronic component comprising a chip and a protective layer disposed on an active surface of the chip;
an encapsulation layer surrounding the electronic component; and
a circuit structure contacting a first surface of the encapsulation layer and electrically connecting the electronic component,
wherein the protective layer has a second surface away from the active surface, and a first step between the first surface and the second surface is between 1-10μ m.

2. The electronic device as claimed in claim 1, wherein the circuit structure comprises a first conductive layer, a first conductive component disposed on the first conductive layer, and a first insulating layer disposed on the first conductive layer and the first conductive component, wherein a second step difference is between the insulating layer surface of the first insulating layer and the conductive component surface of the first conductive component.

3. The electronic device as claimed in claim 2, wherein the second step difference is between 1-15 μm.

4. The electronic device as claimed in claim 2, wherein the electronic device further comprises a connecting component that overlaps the first conductive component.

5. The electronic device as claimed in claim 2, wherein the conductive component surface of the first conductive component comprises a surface protrusion and a surface depression, a first height difference is between a peak of the surface protrusion and a valley of the surface depression, and the first height difference is between 0.1-5 μm.

6. The electronic device as claimed in claim 5, wherein at least a portion of the first insulating layer fills the surface depression of the conductive component surface.

7. The electronic device as claimed in claim 2, wherein an accommodation space is between the first conductive layer and the encapsulation layer, and at least a portion of the first insulating layer is filled into the accommodation space.

8. The electronic device as claimed in claim 7, wherein the accommodation space has a depth of 1-10 μm.

9. A method of manufacturing an electronic device, comprising:
providing an encapsulation layer surrounding an electronic component;
providing a first conductive layer and a first conductive component on the electronic component and the encapsulation layer;
performing a first surface treatment process on the first conductive component;
providing a first insulating layer on the first conductive component subjected to the first surface treatment process;
performing a flattening process; and
performing a second surface treatment process,
wherein the electronic component comprises a chip and a protective layer covering an active surface of the chip, the protective layer has a second surface, the encapsulation layer has a first surface, the second surface and the first surface are separated by a first step difference, and the first step difference is between 1 and 10 μm.

10. The method of manufacturing an electronic device as claimed in claim 9, further comprising providing a connecting component on the circuit structure.

11. The method of manufacturing an electronic device as claimed in claim 9, wherein the flattening process is performed on the first insulating layer, and the conductive component surface of the first conductive component is still covered by the first insulating layer after the flattening process.

12. The method of manufacturing an electronic device as claimed in claim 11, wherein the second surface treatment process comprises performing a partial plasma etching process on a portion of the first insulating layer on the conductive component surface of the first conductive component to expose the conductive component surface of the first conductive component.

13. The method of manufacturing an electronic device as claimed in claim 12, wherein a second step difference is between the insulating layer surface of the first insulating layer and the conductive component surface of the first conductive component.

14. The method of manufacturing an electronic device as claimed in claim 13, wherein the second step difference is between 1 and 15 μm.

15. The method of manufacturing an electronic device as claimed in claim 9, wherein the flattening process is performed on the first insulating layer until the conductive component surface of the first conductive component is exposed.

16. The method of manufacturing an electronic device as claimed in claim 15, wherein the second surface treatment process comprises performing a plasma etching process on the entire first insulating layer, and the method further comprises:
performing a third surface treatment process on the first insulating layer and the first conductive component subjected to the second surface treatment process, wherein the third surface treatment process comprises a chemical etching process.

17. The method of manufacturing an electronic device as claimed in claim 9, wherein the chip comprises a chip back surface opposite the active side, and the flattening process is performed on the first conductive layer, the first conductive component, and the encapsulation layer until the chip back surface of the chip is exposed.

18. The method of manufacturing an electronic device as claimed in claim 17, wherein the second surface treatment process comprises performing a plasma etching process on the entire encapsulation layer to form a third step difference between the other surface of the encapsulation layer and the first conductive component.

19. A method of manufacturing an electronic device, comprising:
providing an encapsulation layer surrounding at least two electronic components;
providing a first conductive layer and a first conductive component on one of the electronic components and the encapsulation layer;
performing a first surface treatment process on the first conductive component;
providing a first insulating layer on the first conductive layer, the first conductive component, and the other electronic component;
forming a third opening through the encapsulation layer between the at least two electronic components;
forming a second conductive layer and a second conductive component on the other electronic component and in the third opening to electrically connect the at least two electronic components;
providing a second insulating layer on the second conductive layer and the second conductive component;
performing a flattening process; and
performing a second surface treatment process,
wherein the electronic component comprises a chip and a protective layer covering an active surface of the chip, the protective layer has a second surface, the encapsulation layer has a first surface, the second surface and the first surface are separated by a first step difference, and the first step difference is between 1 and 10 μm.

20. The method of manufacturing an electronic device as claimed in claim 19, wherein the second conductive component protrudes above the second insulating layer after the second surface treatment process.
